(19) United States
(12) Patent Application Publication
(10) Pub. No.: US 2025/0311274 A1
(43) Pub. Date: Oct. 2, 2025

(54) PACKAGE STRUCTURE OF HIGH ELECTRON MOBILITY TRANSISTOR

(71) Applicant: HiPer Semiconductor Inc., George Town (KY)

(72) Inventor: Cheng-Chieh HSU, Zhubei City (TW)

(21) Appl. No.: 19/078,604

(22) Filed: Mar. 13, 2025

(30) Foreign Application Priority Data
Apr. 1, 2024 (TW) 113112369

(51) Int. Cl. H10D 30/47; H10D 62/85; H10D 64/27

(52) U.S. Cl. CPC H10D 30/471; H10D 62/8503; H10D 64/27

(57) ABSTRACT

The packaging structure of the high electron mobility transistor includes a first terminal, a second terminal, a semiconductor die and a packaging body. The first terminal includes a first platform, a first connection part and multiple first pins. The second terminal includes a second platform, a second connection part and multiple second pins. The semiconductor die includes first electrode and second electrode. The first electrode is coupled to first platform and the second electrode is coupled to second platform. The packaging body encapsulates the semiconductor die, the first platform and the second platform. The first connection part has a first exposed side surface, the second connection part has a second exposed side surface, the first exposed side surface and the second exposed side surface are located outside the package, the first exposed side surface and the second exposed side surface have a first distance D1>2.5 mm.

### BACKGROUND

### 1. Technical Field

The present disclosure is related a high electron mobility transistor (HEMT), specifically to a packaging structure of the high electron mobility transistor.

### 2. Description of the Related Art

Existing packaging technology for gallium nitride (GaN) dies typically requires the formation of a redistribution layer (RDL) on the original GaN die, as disclosed in U.S. Pat. No. 9,589,869. In addition to the redistribution process, such technologies also necessitate additional process steps for growing solder balls or copper pillars on the pads, thereby increasing the complexity of GaN die fabrication. Therefore, there is a need for improvement.

### SUMMARY

It is an object of the present disclosure is to provide a packaging structure of the high electron mobility transistor to reduce the process cost of the above-mentioned fabrication, improve heat dissipation, and minimize parasitic inductance.

To achieve the above objectives, the present disclosure provides a packaging structure of the high electron mobility transistor of the present disclosure includes a first terminal, a second terminal, a semiconductor die, and a packaging body. The first terminal includes a first platform, a first connection part, and a plurality of first pins. The second terminal includes a second platform, a second connection part, and a plurality of second pins. The semiconductor die has a top surface and the top surface has a first electrode and a second electrode. The semiconductor die is configured in a flip-chip arrangement. The first electrode is coupled to the first platform and the second electrode is coupled to the second platform. The packaging body encapsulates the semiconductor die, the first platform, and the second platform. The first pins are located on one side of the packaging body. The second pins are located on another side of the packaging body. The first connection part has a first exposed side surface. The second connection part has a second exposed side surface. The first exposed side surface and the second exposed side surface are located outside packaging body. A first distance D1 exists between the first exposed side surface and the second exposed side surface, wherein the first distance D1 is greater than 2.5 mm.

To achieve the above objectives, the present disclosure further provides a packaging structure of the high electron mobility transistor of the present disclosure includes a first terminal, a second terminal, a third terminal, a fourth pin, a semiconductor die, and a packaging body. The first terminal includes a first platform, a first connection part, and a plurality of first pins, wherein the first connection part is located between the first platform and the first pins. The second terminal includes a second platform, a second connection part, and a plurality of second pins, wherein the second connection part is located between the second platform and the second pins. The third terminal has a third pin. The semiconductor die has a top surface and the top surface has a first electrode, a second electrode, and a control electrode. The semiconductor die is configured in a flip-chip arrangement. The first electrode is coupled to the first platform. The second electrode is coupled to the second platform. The control electrode is coupled to the third terminal. The fourth pin refers as a sensing pin and is coupled to the second terminal. The packaging body encapsulates the semiconductor die, the first platform, and the second platform, wherein the first pins are located on one side of the packaging body. The second pins, the third pin, and the fourth pin are located on another side of the packaging body. The first connection part has a first exposed side surface. The second connection part has a second exposed side surface. The first exposed side surface and the second exposed side surface are located outside the packaging body. A first distance exists between the first exposed side surface and the second exposed side surface, wherein the first distance is greater than 2.5 mm.

The packaging structure of the high electron mobility transistor of the present disclosure simplifies the complex redistribution process traditionally required for gallium nitride (GaN) dies. Additionally, by incorporating a first terminal and a second terminal, both exposed outside the packaging body and spaced apart by a distance greater than 2.5 mm, the packaging structure ensures compliance with the creepage distance requirements for high-voltage HEMT devices. Furthermore, in utilizing TOLL or TOLT package embodiments, the present invention enables dual-sided heat dissipation, thereby reducing the overall thermal resistance of the HEMT packaging structure.

### BRIEF DESCRIPTION OF THE DRAWINGS

FIG. 1 is a schematic diagram of a first embodiment of the packaging structure for a high electron mobility transistor according to the present disclosure.

FIG. 2 is a cross-sectional view taken along line AA′ of FIG. 1.

FIG. 3 is a schematic cross-sectional view of an embodiment of a semiconductor die with a first platform and a second platform.

FIG. 4 is a schematic diagram of a second embodiment of the packaging structure for a high electron mobility transistor according to the present disclosure.

FIG. 5 is a cross-sectional view taken along line BB′ of FIG. 4.

FIG. 6 is a schematic diagram of a third embodiment of the packaging structure for a high electron mobility transistor according to the present disclosure.

FIG. 7 is a cross-sectional view taken along line CC′ of FIG. 6.

FIG. 8 is a schematic diagram of a fourth embodiment of the packaging structure for a high electron mobility transistor according to the present disclosure.

FIG. 9 is a cross-sectional view taken along line DD′ of FIG. 8.

FIG. 10 is a schematic diagram of a fifth embodiment of the packaging structure for a high electron mobility transistor according to the present disclosure.

FIG. 11 is a cross-sectional view taken along line EE′ of FIG. 10.

### DETAILED DESCRIPTION OF THE EMBODIMENTS

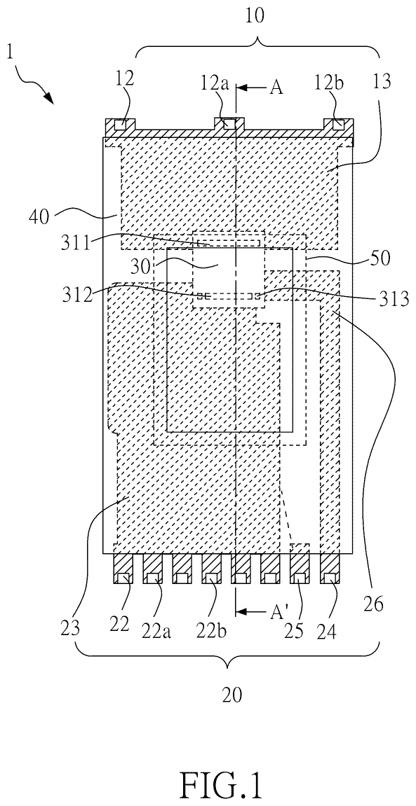

In order to make the structure and characteristics as well as the effectiveness of the present disclosure further understood and recognized, a detailed description of the present disclosure is provided as follows, along with embodiments and accompanying figures. Please refer to FIG. 1 to FIG. 3 relating to a schematic diagram of a first embodiment of the packaging structure for a high electron mobility transistor according to the present disclosure, a cross-sectional view taken along line AA′ of FIG. 1, and a schematic cross-sectional view of an embodiment of a semiconductor die with a first platform and a second platform.

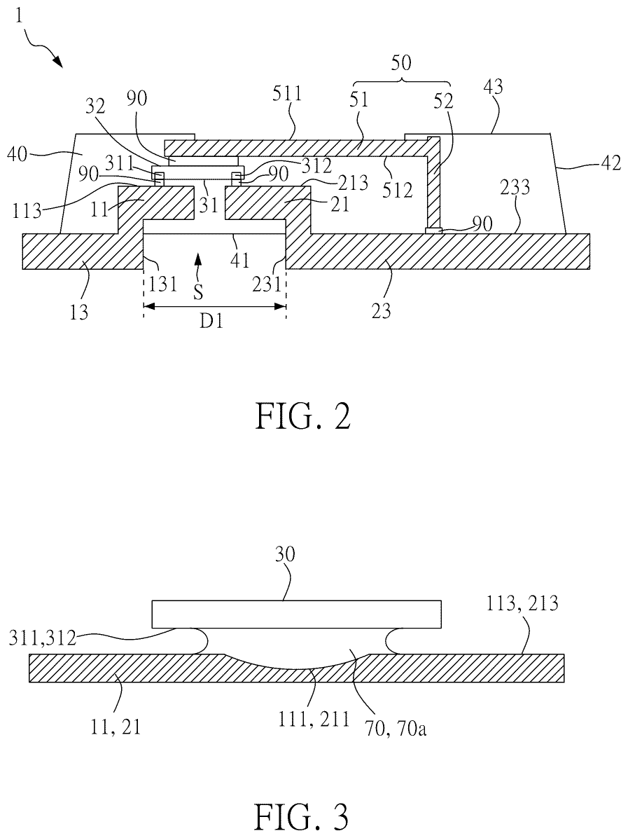

As shown in FIG. 1 and FIG. 2, a packaging structure of the high electron mobility transistor 1 of the present disclosure includes a first terminal 10, a second terminal 20, a semiconductor die 30, and a packaging body 40. The semiconductor die 30 is located above the first terminal 10 and the second terminal 20. The packaging body 40 encapsulates the semiconductor die 30, a portion of first terminal 10, and a portion of the second terminal 20. In the first embodiment, the first terminal 10 includes a first platform 11, a plurality of first pins 12, 12a, 12b, and a first connection part 13. The first connection part 13 is located between the first platform 11 and the first pins 12, 12a, 12b. The second terminal 20 includes a second platform 21, a plurality of second pins 22, 22a, 22b, and a second connection part 23. The second connection part 23 is located between the second platform 21 and the second pins 22, 22a, 22b. Furthermore, the packaging structure 1 further includes a fourth pin 25 and a third terminal 26. The third terminal 26 has a third pin 24. The first pins 12, 12a, 12b, as above mentioned, are located on one side of the packaging body 40. The second pins 22, 22a, 22b, the third pin 24, and the fourth pin 25 are located on another side of the packaging body 40. According to an embodiment of the present disclosure, the combination of the first terminal 10, the second terminal 20, and the third terminal 26 constitutes a lead frame.

As shown in FIG. 1 and FIG. 2, the semiconductor die 30 of this embodiment is a gallium nitride (GaN) die or a silicon carbide (SiC) die, which includes a top surface 31 and a bottom surface 32. The top surface 31 includes a first electrode 311, a second electrode 312, and a third electrode 313. The semiconductor die 30 is flip-chip mounted on the first terminal 10 and the second terminal 20. The semiconductor die 30, through solder paste 90, couples the first electrode 311 of the semiconductor die 30 to the first platform 11 and the second electrode 312 to the second platform 21. In this embodiment, the first electrode 311 serves as the drain, the first platform 11 is coupled to the first electrode 311 through solder paste 90. Accordingly, the first pins 12, 12a, 12b function as drain pins. The second electrode 312 serves as the source, and the second platform 21 is coupled to the second electrode 312 through solder paste 90. Therefore, the second pins 22, 22a, 22b function as source pins. The third electrode 313 is the control electrode, or the gate, and the third electrode 313 is coupled to the third terminal 26 through solder paste, making the third pin 24 functioned as gate pin. The fourth pin 25 of this embodiment functions as a sensing pin and is coupled to the second connection part 23 of the second terminal 20 through wire bonding.

As shown in FIG. 2, in the first embodiment, the first connection part 13 and the second connection part 23 are L-shaped, with the short sides of the two L-shaped structures respectively connected to the first platform 11 and the second platform 21. These short sides extend vertically beyond the packaging body bottom surface 41, thereby exposing the short side of the L-shaped first connection part 13 at the packaging body bottom surface 41, forming a first exposed side surface 131. Similarly, the short side of the L-shaped second connection part 23 is exposed at the packaging body bottom surface 41, forming a second exposed side surface 231. The first exposed side surface 131 and the second exposed side surface 231 are separated by a first distance D1, wherein the first distance D1 is greater than 2.5 mm. This configuration ensures compliance with the creepage distance requirements for high-voltage high electron mobility transistor (HEMT) devices, thereby reducing parasitic inductance. Specifically, the embodiment shown in FIG. 2 adopts a TOLL (Transistor Outline Leadless) package. As shown in FIG. 1 and FIG. 2, the packaging structure of the high electron mobility transistor 1 in this embodiment further forms a heat dissipation space “S” among the packaging body bottom surface 41, the first exposed side surface 131, and the second exposed side surface 231. Additionally, the long sides of the L-shaped first connection part 13 and the long sides of the L-shaped second connection part 23 respectively extend along the packaging body bottom surface 41 in a direction away from the semiconductor die 30, extending beyond the packaging body side surface 42. Furthermore, the bottom surfaces of the long sides of the L-shaped first connection part 13 and the bottom surfaces of the long sides of the L-shaped second connection part 23 do not contact the surface of the packaging body 40 but instead exposed at the packaging body bottom surface 41.

As shown in FIG. 1 and FIG. 2, the packaging structure of the high electron mobility transistor 1 of the present disclosure further includes a metal sheet 50, wherein a portion of the first surface 511 of the metal sheet 50 is exposed at the packaging body top surface 43. This configuration facilitates double-sided heat dissipation, thereby reducing the overall thermal resistance of the packaging structure of the high electron mobility transistor 1. Specifically, as shown in FIG. 2, the second connection part 23 includes an inner surface 231. In this embodiment, the metal sheet 50 further includes a horizontal portion 51 and a vertical portion 52, wherein the second surface 512 of the horizontal portion 51, which faces away from the packaging body top surface 43, is coupled to the bottom surface 32 of the semiconductor die 30 through solder paste 90. One side of the horizontal portion 51, which is not coupled to the bottom surface 32 of the semiconductor die 30, is connected to the vertical portion 52. One end of the vertical portion 52, which is not connected to the horizontal portion 51, is coupled to the inner surface 233 of the second connection part 23 through solder paste 90.

As shown in FIG. 3, according to an embodiment of the present disclosure, to enhance the soldering reliability between the first electrode 311 and the first platform 11, as well as between the second electrode 312 and the second platform 21, the packaging structure of the high electron mobility transistor 1 further includes a first recessed portion 111 formed within the first platform 11 and a second recessed portion 211 formed within the second platform 21. The first recessed portion 111 and the second recessed portion 211 are configured to respectively accommodate the first solder 70 and second solder 70a, wherein the first solder 70 and the second solder 70a are solder paste.

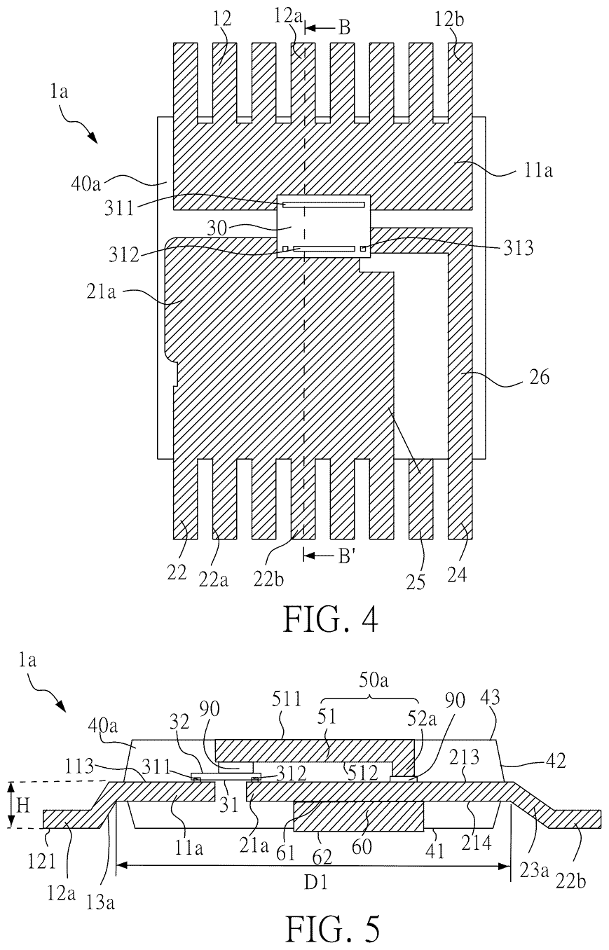

Please refer to FIG. 4 and FIG. 5 relates to a schematic diagram of a second embodiment of the packaging structure for a high electron mobility transistor according to the present disclosure and a cross-sectional view taken along line BB′ of FIG. 4.

As shown in FIG. 4 and FIG. 5, in the second embodiment, the packaging structure of the high electron mobility transistor la of the present disclosure is an example of TOLT packaging. In second embodiment, the first platform 11a and the second platform 21a of packaging structure of the high electron mobility transistor la of the present disclosure extend horizontally beyond the packaging body side surface 42. The first connection part 13a and the second connection part 23a are inclined and connected to the first platform 11a and the second platform 21, which are exposed at the packaging body side surface 42. Accordingly, in this embodiment, the first distance D1 between the first exposed side surface 131 and the second exposed side surface 231 is defined as the distance between the connection point of the first connection part 13a and the first platform 11a, and the connection point of the second connection part 23a and second platform 21a. As shown in FIG. 5, the first connection part 13a is connected to the first pin 12a at one end that is not connected to the first platform 11a, while the second connection part 23a is connected to the second pin 22a at one end that is not connected to the second platform 21a. In this embodiment, the first platform 11a has a first electrode contact surface 113, and the first pin 12 has a pin bottom surface 121. A vertical distance H is defined between the first electrode contact surface 113 and the pin bottom surface 121, wherein H>0.3 mm.

As shown in FIG. 4 and FIG. 5, the second embodiment of the packaging structure of the high electron mobility transistor la further includes a heat dissipation material 60. The second platform 21a includes an upper surface 213 and a lower surface 214, which is opposite to the upper surface 213. The first heat dissipation surface 61 of the heat dissipation material 60 is located on the lower surface 214. The second heat dissipation surface 62 of the heat dissipation material 60, which is not connected to the lower surface 214, is exposed at the packaging body bottom surface 41. Furthermore, in this embodiment, the metal sheet 50a is L-shaped, wherein two opposite sides of the metal sheet 50a in contact with the upper surface 213 and the bottom surface 32 of the semiconductor die 30 respectively through solder paste 90. Specifically, the horizontal portion 51 of the metal sheet 50a has two opposite ends, wherein one end is connected to the bottom surface 32 of the semiconductor die 30, and the other end is connected to the vertical portion 52a. The vertical portion 52a has one end that is not connected to the horizontal portion 51 but is instead coupled to the upper surface 213. According to an embodiment of the present disclosure, the horizontal portion 51 can be in contact with or exposed at the packaging body top surface 43. This configuration facilitates double-sided heat dissipation, thereby reducing the overall thermal resistance of the packaging structure of the high electron mobility transistor la.

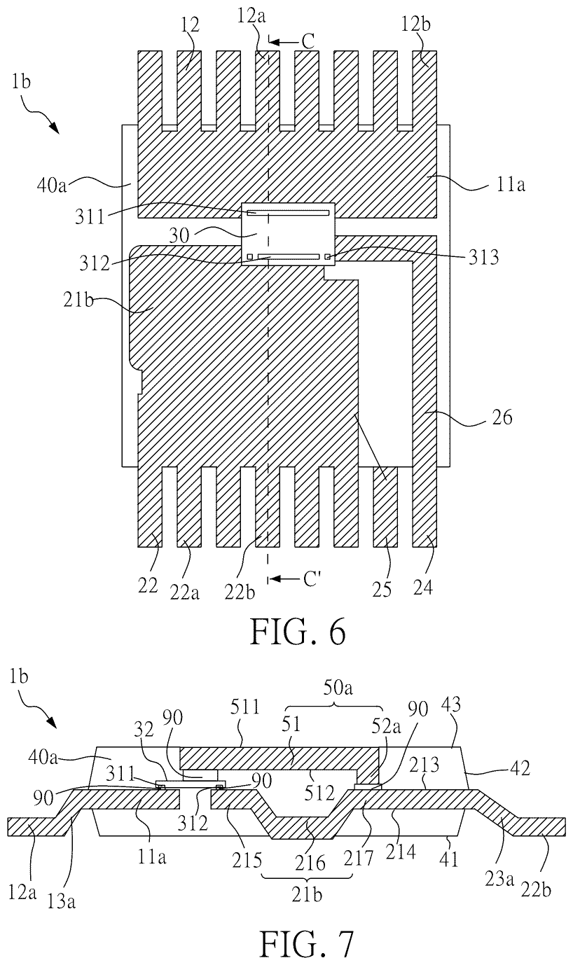

Please refer to FIG. 6 and FIG. 7 relating to a schematic diagram of a third embodiment of the packaging structure for a high electron mobility transistor according to the present disclosure and a cross-sectional view taken along line CC′ of FIG. 6.

As shown in FIG. 6 and FIG. 7, the third embodiment of the packaging structure of the high electron mobility transistor 1b of the present disclosure differs from the second embodiment in that the second platform 21b of the packaging structure of the high electron mobility transistor 1b of the present disclosure includes a second electrode connection part 215, a second heat dissipation part 216, and a second pin connection part 217. The second heat dissipation part 216 has two opposite ends, wherein one end is connected to the second electrode connection part 215 and the other end is connected to the second pin connection part 217. Additionally, the upper surface 213 of the second platform 21b is located at the second pin connection part 217, which is connected to the second connection part 23a. The first electrode connection part 215 and the second pin connection part 217 are aligned on the same horizontal plane. The second heat dissipation part 216 is located lower than both the second electrode connection part 215 and the second pin connection part 217, with one surface of the second heat dissipation part 216 exposed at the packaging body bottom surface 41 of the packaging body 40. Furthermore, in this embodiment, the semiconductor die 30 is coupled to the second electrode connection part 215 through solder paste 90. The vertical portion 52a of the metal sheet 50a is coupled to the upper surface 213, which is located on the second pin connection part 217.

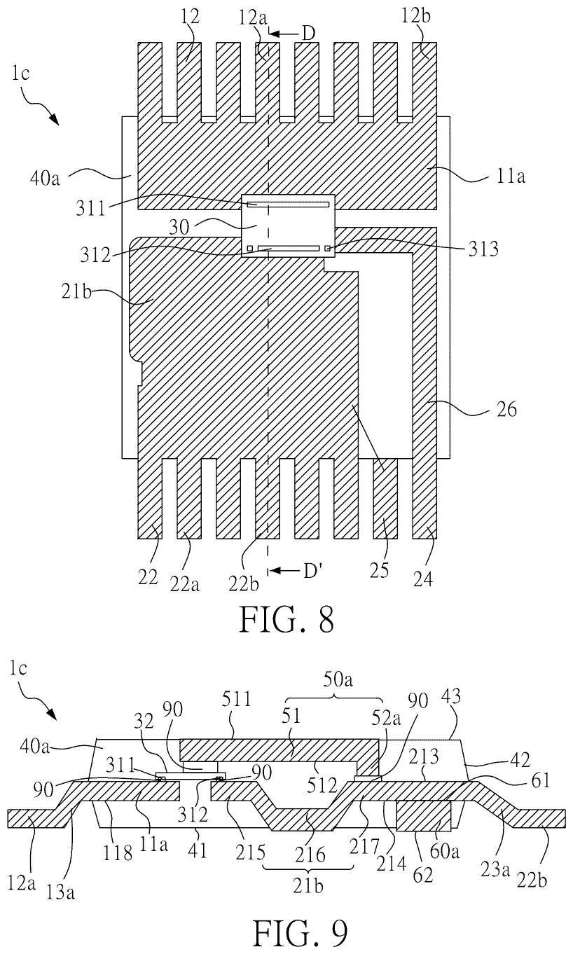

Please refer to FIG. 8 and FIG. 9 relates to a schematic diagram of a fourth embodiment of the packaging structure for a high electron mobility transistor according to the present disclosure and a cross-sectional view taken along line DD′ of FIG. 8.

It is noted that the fourth embodiment of the packaging structure of the high electron mobility transistor 1c differs from the second embodiment of packaging structure of the high electron mobility transistor 1b in that the packaging structure of the high electron mobility transistor 1c further includes a heat dissipation member 60a. The first heat dissipation surface 61 of the heat dissipation material 60a is positioned on the side of the second pin connection part 217 that is closer to the packaging body bottom surface 41. Meanwhile, the second heat dissipation surface 62 of the heat dissipation material 60, which is not connected to the second pin connection part 217, is exposed at the packaging body bottom surface 41.

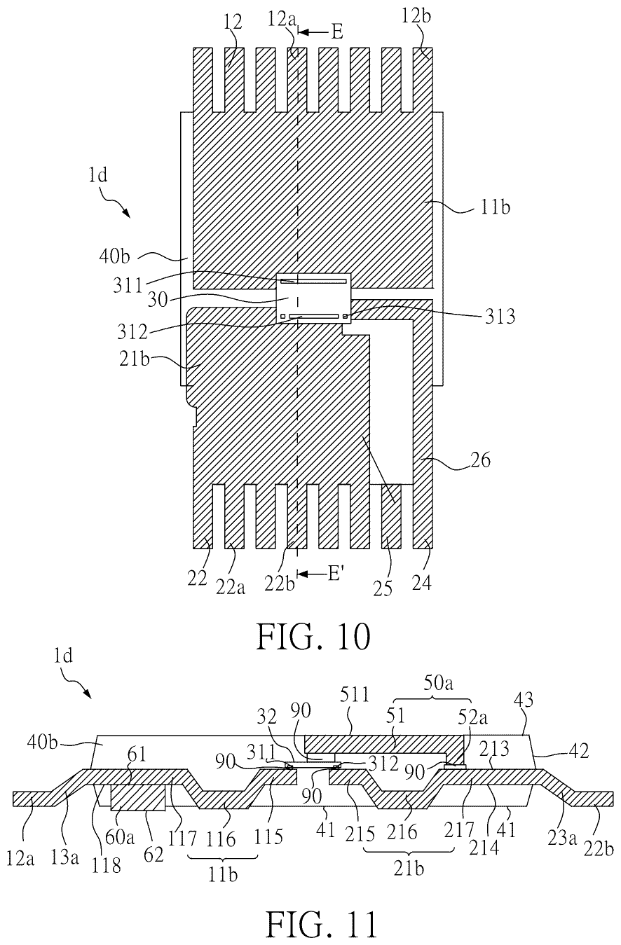

Please refer to FIG. 10 and FIG. 11 relating to a schematic diagram of a fifth embodiment of the packaging structure for a high electron mobility transistor according to the present disclosure and a cross-sectional view taken along line EE′ of FIG. 10.

It is noted that, the fifth embodiment of the packaging structure of the high electron mobility transistor 1d differs from the fourth embodiment of the packaging structure of the high electron mobility transistor 1c in that the first platform 11b of the packaging structure of the high electron mobility transistor 1d further includes a first electrode connection part 115, a first heat dissipation part 116, and a first pin connection part 117. The first heat dissipation part 116 locates between the first electrode connection part 115 and the first pin connection part 117. The first electrode connection part 115 is coupled to the first electrode 311, and the first pin connection part 117 connects to the first connection part 13a. The first heat dissipation part 116 has one side facing away from the semiconductor die 30, which is exposed at the packaging body bottom surface 41. Furthermore, according to an embodiment of the present disclosure, the packaging structure of the high electron mobility transistor 1d can also include one or more heat dissipation materials 60a. The heat dissipation materials 60a can be positioned on a side of the first pin connection part 117 that is closer to the packaging body bottom surface 41 (i.e., the lower surface 118 of the first platform 11b), and/or a side of the second pin connection part 217 that is closer to the packaging body bottom surface 41 (i.e., the lower surface 214 of the second platform 11b).

By utilizing the packaging structure of the high electron mobility transistor 1, 1a, 1b, 1c, 1d of the present disclosure, the complex redistribution process traditionally required for gallium nitride (GaN) dies can be simplified. Additionally, the spacing greater than 2.5 mm between the first terminal and the second terminal, both exposed to the packaging body 40, 40a, effectively reduces parasitic inductance and ensures compliance with the creepage distance requirements for high-voltage HEMT devices. Furthermore, in the TOLL and TOLT package embodiments, the packaging structure of the high electron mobility transistor 1, 1a, 1b, 1c, 1d of the present disclosure exhibits dual-sided heat dissipation, thereby further reducing the overall thermal resistance of the packaging structure of the high electron mobility transistor 1, 1a, 1b, 1c, 1d.

It should be noted that many of the above-mentioned embodiments are given as examples for description, and the scope of the present invention should be limited to the scope of the following claims and not limited by the above embodiments.

What is claimed is:

1. A packaging structure of a high electron mobility transistor (HEMT), comprising:
a first terminal, including a first platform, a first connection part, and a plurality of first pins, wherein the first connection part are located between the first platform and the first pins;
a second terminal, including a second platform, a second connection part, and a plurality of second pins, wherein the second connection part are located between the second platform and the second pins;
a semiconductor die, having a top surface, the top surface having a first electrode and a second electrode, the semiconductor die being flip-chip mounted, the first electrode coupled to the first platform and the second electrode coupled to the second platform; and
a packaging body, encapsulating the semiconductor die, the first platform, and the second platform, wherein the first pins are located on one side of the packaging body, and the second pins are located on another side of the packaging body; the first connection part has a first exposed side surface, and the second connection part has a second exposed side surface; the first exposed side surface and the second exposed side surface are located outside the packaging body; a first distance exists between the first exposed side surface and the second exposed side surface, and the first distance is greater than 2.5 mm.

2. The packaging structure as claimed in claim 1, further comprising a metal sheet, wherein the second connection part has an inner surface inside the packaging body, and the semiconductor die has a bottom surface, wherein two opposite ends of the metal sheet are coupled to the inner surface of the second connection part and the bottom surface of the semiconductor die, respectively.

3. The packaging structure as claimed in claim 2, wherein the metal sheet includes a horizontal portion and a vertical portion, wherein two opposite ends of the horizontal portion are coupled to the bottom surface of the semiconductor die and the vertical portion, the horizontal portion having a first surface and a second surface, the first surface is at least partially exposed outside the packaging body, and the second surface is at least partially coupled to the bottom surface of the semiconductor die.

4. The Packaging structure as claimed in claim 1, wherein the semiconductor die is a gallium nitride die or a silicon carbide die.

5. The packaging structure as claimed in claim 1, wherein the first platform has a first recessed portion, the semiconductor die being disposed on the first platform through a first solder and the first recessed portion, wherein the first solder is filed into the first recessed portion.

6. The packaging structure as claimed in claim 5, wherein the second platform has a second recessed portion, the semiconductor die being disposed on the second platform through a second solder and the second recessed portion.

7. The packaging structure as claimed in claim 1, wherein the first platform has a first electrode contact surface, each of the first pins has a pin bottom surface, the pin bottom surface being located outside the packaging body, a vertical distance existing between the first electrode contact surface and the pin bottom surface, and the vertical distance is greater than 0.3 mm.

8. The packaging structure as claimed in claim 1, wherein the packaging body includes a packaging body bottom surface, and the first exposed side surface, the second exposed side surface and the packaging body bottom surface form a heat dissipation space.

9. The packaging structure as claimed in claim 1, further comprising a heat dissipation material, the heat dissipation material having a first heat dissipation surface and a second heat dissipation surface, both the first platform and the second platform having a bottom surface, the first heat dissipation surface of the heat dissipation material contacting the bottom surface of the first platform, and/or contacting the bottom surface of the second platform, and the second heat dissipation surface of the heat dissipation material being exposed outside the packaging body.

10. The packaging structure as claimed in claim 1, further comprising a metal sheet, wherein the semiconductor die includes a bottom surface, and the second platform includes an upper surface, wherein two opposite ends of the metal sheet are coupled to the upper surface and the bottom surface, respectively.

11. The packaging structure as claimed in claim 1, wherein the first platform further includes a first electrode connection part, a first heat dissipation part, and a first pin connection part, wherein the first heat dissipation part is located between the first electrode connection part and the first pin connection part, the first electrode connection part is coupled to the first electrode, the first pin connection part is connected to the first connection part, and one surface of the first heat dissipation part is exposed outside the packaging body.

12. The packaging structure as claimed in claim 11, further comprising a heat dissipation material, the heat dissipation material having a first heat dissipation surface and a second heat dissipation surface, wherein the first heat dissipation surface of the heat dissipation material contacts the first pin connection part, and the second heat dissipation surface of the heat dissipation material is exposed outside the packaging body.

13. The packaging structure as claimed in claim 11, wherein the second platform further includes a second electrode connection part, a second heat dissipation part, and a second pin connection part, wherein the second heat dissipation part is located between the second electrode connection part and the second pin connection part, the second electrode connection part is coupled to the second electrode, the second pin connection part is connected to the second connection part, and one surface of the second heat dissipation part is exposed outside the packaging body.

14. The packaging structure as claimed in claim 13, further comprising a heat dissipation member, the heat dissipation material having a first heat dissipation surface and a second heat dissipation surface, wherein the first heat dissipation surface of the heat dissipation material contacts the second pin connection part, and the second heat dissipation surface of the heat dissipation material is exposed outside the packaging body.

15. The packaging structure as claimed in claim 1, further comprising a third pin and a fourth pin, the third pin and the fourth pin being located on another side of the packaging body, wherein the third pin is a gate pin, and the fourth pin is a sensing pin.

16. The packaging structure as claimed in claim 15, wherein the fourth pin is coupled to the second connection part of the second terminal through wire bonding.

17. A packaging structure of a high electron mobility transistor (HEMT), comprising:
a first terminal,
including a first platform, a first connection part, and a plurality of first pins, wherein the first connection part is located between the first platform and the first pins;
a second terminal, including a second platform, a second connection part, and a plurality of second pins, wherein the second connection part is located between the second platform and the second pins;
a third terminal, having a third pin;
a fourth pin;
a semiconductor die, having a top surface, the top surface having a first electrode, a second electrode, and a control electrode, the semiconductor die being flip-chip mounted, wherein the first electrode is coupled to the first platform, the second electrode is coupled to the second platform, and the control electrode is coupled to the third terminal, wherein the fourth pin is a sensing pin and is coupled to the second terminal; and
a packaging body encapsulating the semiconductor die, the first platform, and the second platform, wherein the first pins are located on one side of the packaging body, and the second pins, the third pin, and the fourth pin are located on another side of the packaging body, wherein the first connection part has a first exposed side surface and the second connection part has a second exposed side surface, the first exposed side surface and the second exposed side surface locating outside the packaging body, wherein a first distance exists between the first exposed side surface and the second exposed side surface, the first distance being greater than 2.5 mm.
